(19) United States
(12) Patent Application Publication
(10) Pub. No.: US 2023/0343669 A1
(43) Pub. Date: Oct. 26, 2023

(54) ELECTRONIC PACKAGING STRUCTURE

(71) Applicant: SJ Semiconductor(Jiangyin) Corporation, Jiangyin City (CN)

(72) Inventors: Chengchung Lin, Jiangyin City (CN); Jin Yang, Jiangyin City (CN)

(21) Appl. No.: 18/137,994

(22) Filed: Apr. 21, 2023

(30) Foreign Application Priority Data
Apr. 21, 2022 (CN) 202210425127.2

(51) Int. Cl. H01L 23/367; H01L 25/065; H01L 23/00; H01L 23/42

(52) U.S. Cl. CPC H01L 23/367; H01L 25/0655; H01L 24/32; H01L 23/42; H01L 2224/32245

(57) ABSTRACT

An electronic packaging structure has been provided, which comprises: one or more chips, a substrate, and a heat sink cover; the chips are mounted on the substrate; the heat sink cover includes a supporting part and a top cover, the supporting part is bonded to the substrate, and surrounds the chips; the top cover is supported by the supporting part and covers the chips, and the top cover includes slits whose positions align to gaps near or between the chips. A first window can be formed in the top cover, and partially exposes a high-power-density chip; a second window next to the high-power-density chip can also be formed in the supporting part. By providing the slits, the first window above the chip, and the second window at sides of the chip, the technique minimizes heat transfer between the chips and reduce risk of thermal crosstalk while retaining package warpage control.

### CROSS REFERENCE TO RELATED APPLICATION

The present application claims the benefit of priority to Chinese Patent Application No. CN 202210425127.2, entitled “ELECTRONIC PACKAGING STRUCTURE”, filed with CNIPA on Apr. 21, 2022, the disclosure of which is incorporated herein by reference in its entirety for all purposes.

### FIELD OF TECHNOLOGY

The present disclosure generally relates to semiconductor packaging, and in particular, to an electronic packaging structure.

### BACKGROUND

In recent years, integrated circuit packaging has undergone rapid development from 2D integrated circuit packaging to 2.5D and 3D integrated circuit packaging driven by growing performance demand. Standard flip-chip ball-grid-array (BGA) or land-grid-array (LGA) packages are important electronic packaging products, where the chips are flipped and welded to a substrate, and then a heat sink cover is placed on the chips, with the heat sink cover fixed to the chips and the substrate. The heat sink cover can provide a heat dissipation path from the chips to external thermal management hardware, thereby enhancing heat dissipation capability of the product.

During the operation of the chips, some portion of the heat generated is transferred out to the external heat sink through the heat sink cover, and some portion of the heat is transferred laterally between adjacent chips through the heat sink cover, resulting in thermal crosstalk between the chips and causing thermal risks to the neighboring chips, especially the ones with high power density.

Therefore, developing an electronic packaging structure that can reduce thermal crosstalk between chips that are packaged together is a challenge facing those skilled in the art.

### SUMMARY

The present disclosure provides an electronic packaging structure, comprising: one or more chips, a substrate, and a heat sink cover; wherein the chips are mounted on the substrate; wherein the heat sink cover includes a supporting part and a top cover, the supporting part is bonded to the substrate, and surrounds the chips; the top cover is supported by the supporting part and covers the chips, and the top cover includes slits whose positions aligned to gaps near or between the chips.

In one embodiment, the plurality of chips comprises at least one high-power-density chip, wherein a first window is formed in the top cover and at least partially exposes the high-power-density chip.

In one embodiment, an area of the first window is greater than or equal to an area of an upper surface of the high-power-density chip.

In one embodiment, a second window next to the high-power-density chip is formed in the supporting part.

In one embodiment, a total area of the slits is less than or equal to a total area of the gaps near or between the chips.

In one embodiment, each of the slits include sub-slits, wherein each of the sub-slits is arranged in an array.

In one embodiment, the electronic packaging further comprises a first thermal interface material layer, wherein the top cover is adhered to upper surfaces of the chips through the first thermal interface material layer.

In one embodiment, the electronic packaging further comprises a second thermal interface material layer, wherein the top cover is adhered to an external heat sink through the second thermal interface material layer.

In one embodiment, the supporting part is bonded to the substrate by a sealant.

### BRIEF DESCRIPTION OF THE DRAWINGS

FIG. 1 is a cross-sectional view of an electronic packaging structure according to one embodiment of the present disclosure.

FIG. 2 is a top view of an electronic packaging structure according to one embodiment of the present disclosure.

FIG. 3 is a top view of an electronic packaging structure according to one embodiment of the present disclosure.

FIG. 4 is a cross-sectional view of an electronic packaging structure according to one embodiment of the present disclosure.

FIG. 5 is a top view of an electronic packaging structure according to one embodiment of the present disclosure.

FIG. 6 is a cross-sectional view of an electronic packaging structure according to one embodiment of the present disclosure.

FIG. 7 is a top view of an electronic packaging structure according to one embodiment of the present disclosure.

FIG. 8 is a schematic diagram of an electronic packaging structure when working together with an external heat sink.

### REFERENCE NUMERALS

101, 102, 103 Chips

2 Substrate

3 Heat Sink Cover

301 Supporting Part

302 Top Cover

4 Slit

401 Sub-slit

5 First Window

6 Second Window

7 First Thermal Interface Material Layer

8 Second Thermal Interface Material Layer

9 Heat Sink

10 Sealant

### DETAILED DESCRIPTION

The following describes the implementation of the present disclosure through specific examples, and those skilled in the art can easily understand other advantages and effects of the present disclosure from the content disclosed in this specification. The present disclosure can also be implemented or applied through other different specific embodiments. Various details in this specification can also be modified or changed based on different viewpoints and applications without departing from the spirit of the present disclosure.

It should be noted that the drawings provided in this disclosure only illustrate the basic concept of the present disclosure in a schematic way, so the drawings only show the components related to the present disclosure. The drawings are not necessarily drawn according to the number, shape, and size of the components in actual implementation; during the actual implementation, the type, quantity, and proportion of each component can be changed as needed, and the components' layout may also be more complicated.

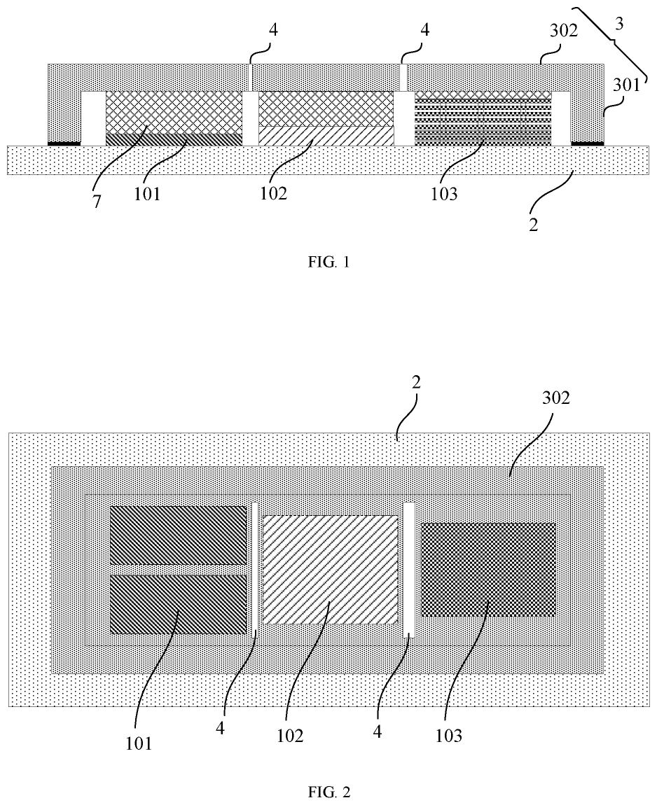

As shown in FIGS. 1 and 2, an electronic packaging structure has been provided, which comprises: a multiple chips 101, 102, 103, a substrate 2 and a heat sink cover 3; multiple chips are mounted on the substrate 2; the heat sink cover 3 includes a supporting part 301 and a top cover 302, footings of the supporting part 301 is bonded to the substrate 2, and surrounds the chips; the top cover 302 is supported by the supporting part 301 and covers the chips from the top, and the top cover 302 includes slits 4 whose positions align to gaps near or between the chips.

The chips may be some of those semiconductor chips needed to be packaged, and may be different types of chips including for example, a system-on-chip (SOC) device, or a memory chip, or a high bandwidth memory (HBM) chip or an assemble of them, etc. In addition, requirements of package efficiency, package size, etc., typically demand way more than two chips packaged together. The attached drawings take three chips 101, 102, 103 in the package as an example.

The slits 4 are set in the top cover 302, and aligned to gaps near or between different chips (e.g., near or between chips of different types); as a result, heat transfer near or between these chips can be reduced, thereby reducing the risk of thermal crosstalk.

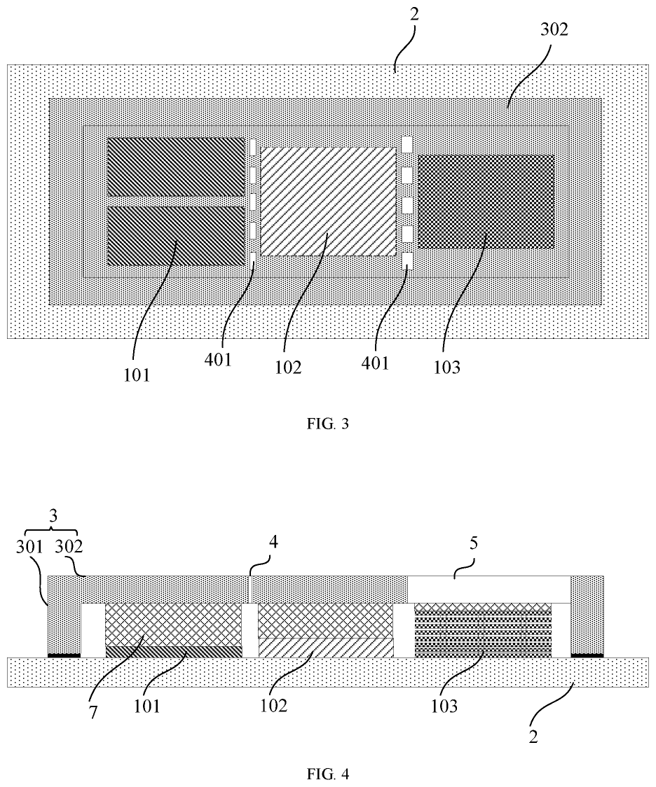

In one embodiment, each of the slits 4 may include a number of sub-slits 401, wherein each of the sub-slits is arranged in an array. As shown in FIG. 3, each of the slits 4 includes a row of sub-slits 401; the sub-slits 401 can be in a variety of other arrangements. In addition, the shape and number of the sub-slits 401 may be arranged differently. In general, slits have elongated shape, the narrower side, i.e., the width of the slits 4 can be designed wide enough for heat transfer yet not affecting the rigidity of the heat sink cover 3, in order to take full advantage of the gaps near or between the chips, and the longer side, i.e., the length of the slits can be designed long enough for heat transfer within the allowed gap space, in order to better limit the lateral transfer of heat between the chips.

As an example, the slits 4 have a total area less than or equal to that of the gaps near or between the chips. As an example, each of the slits 4 has an area equal to that of its immediate neighboring gap.

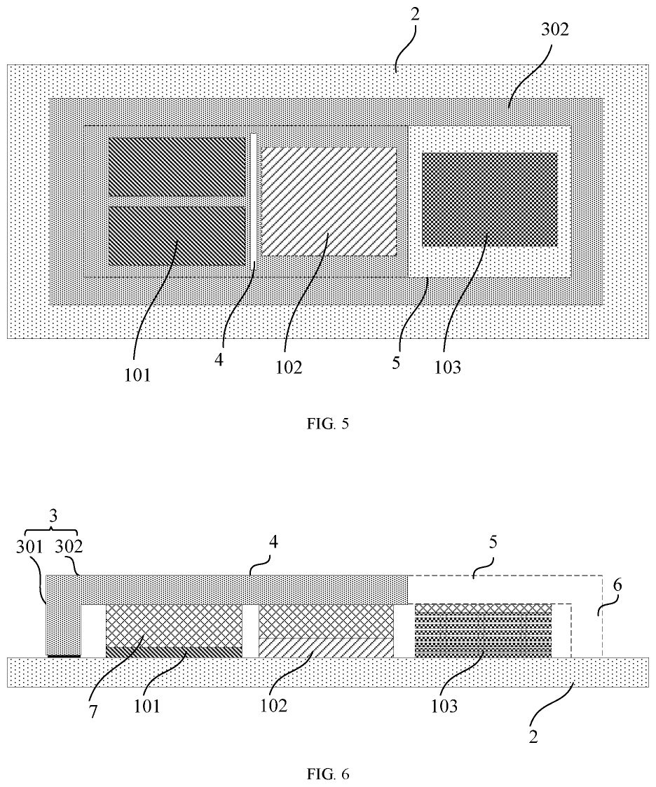

As an example, as shown in FIGS. 4 and 5, the multiple chips inside each cover may include one high-power-density chip 103, here the top cover 302 has a first window 5 exposing the high-power-density chip 103. The high-power-density chip 103, such as an HBM, has a stacked chip structure with high density so it is more difficult for it to dissipate heat than lower density and lower power chips; by forming a larger window 5 at a position of the top cover 302 aligned to the high-power-density chip 103, the heat of the high-power-density chip 103 can be directly dissipated out first through the top window, and meanwhile lateral heat dissipation to adjacent chips is also mitigated through the heat sink cover 3.

As an example, an area of the first window 5 is greater than or equal to the area of the upper surface of the high-power-density chip 103. In other words, the entire upper surface of the high-power-density chip 103 is exposed by window 5, thus reducing the lateral heat transfer from the high-power-density chip 103 to other chips, especially to adjacent chips.

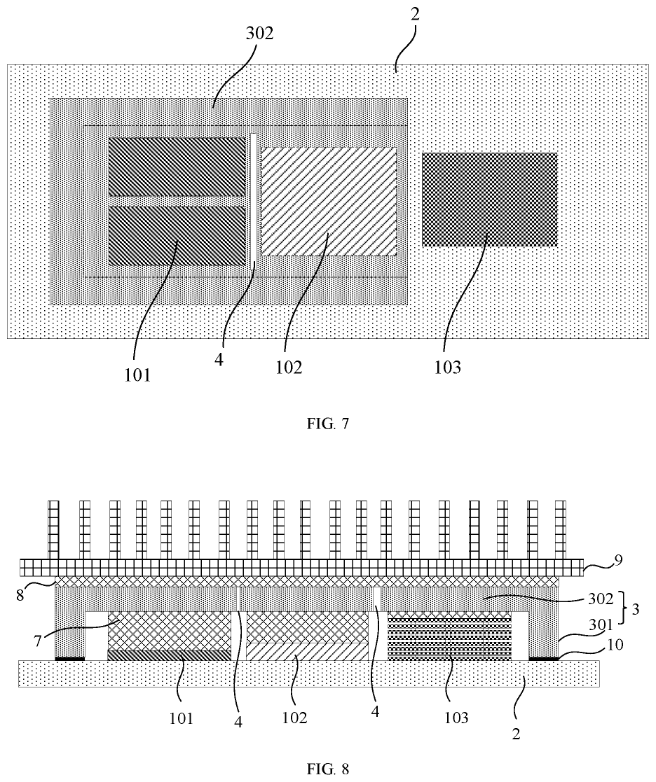

As an example, a second window 6 is formed next to the high-power-density chip 103 in the supporting part 301, as shown in FIGS. 6 and 7. In other words, in addition to exposing the upper surface of the high-power-density chip 103, side surfaces of the high-power-density chip 103 are also exposed, reducing heat transfer from the high-power-density chip 103 to other chips, especially to neighboring chips. For ease of illustration and clarity, the first window 5 and the second window 6 are shown as dashed lines in FIG. 6.

As an example, materials of the heat sink cover 3 include one or more of copper, iron, tungsten, molybdenum, and other suitable metal materials. Preferably, in one example, the heat sink cover 3 is made of copper and plated with nickel to prevent corrosion.

Further, as shown in FIG. 1, FIG. 4, FIG. 6 and FIG. 8, the packaging structure further comprises a first thermal interface material (TIM) layer 7, and the top cover 302 is adhered to upper surfaces of the chips 101, 102, 103 through the first thermal interface material layer 7. The first thermal interface material layer 7 may be made of polymer TIM, solid TIM, or other materials; for example, thermally conductive silicone may be selected to form the first thermal interface material layer 7. The thermal interface material layer 7 avoids or minimizes air inclusions, thereby achieving efficient heat transfer near or between the heat source (e.g., the chips) and the heat sink 9. Moreover, the thermal interface material layer 7 can also act as a bonding agent to bond the top cover 302 and the upper surfaces of the chips 101, 102, 103 together.

Further, as shown in FIG. 8, the packaging structure further comprises a second thermal interface material layer 8, and the top cover 302 is adhered to an external heat sink 9 through the second thermal interface material layer 8. Materials of the second thermal interface material layer 8 may be the same as those of the first thermal interface material layer 7; the external heat sink 9 includes, but is not limited to, an air-cooling heat sink, a liquid cooling plate, etc.

It should be noted that, in the case shown in FIGS. 4 and 5, where the heat sink cover 3 has the first window 5, the first thermal interface material layer 7 is optional; that is, the heat dissipation path of the high-power-density chip 103 includes from top of the chip 103 to the second thermal interface material layer 8, then to the external heat sink 9. Similarly, in the case shown in FIGS. 6 and 7, where the heat sink cover 3 has the first window 5 and the second window 6, the first thermal interface material layer 7 is optional; that is, the heat dissipation path of the high-power-density chip 103 is: from the chip 103 to the second thermal interface material layer 8, and then to the external heat sink 9.

As an example, the supporting part 301 is bonded to the substrate 2 by a sealant 10 shown in FIG. 8. In the electronic packaging structure shown in FIGS. 1 and 4, the bottom surface of the supporting part 301 in contact with the substrate 2 has four side strips, and therefore the sealant 10 is applied to the four side strips of the supporting part 301; in the electronic packaging structure shown in FIG. 6, the bottom surface of the supporting part 301 in contact with the substrate 2 has three side strips, and therefore the sealant 10 is applied to the three side strips of the supporting part 301.

In summary, an electronic packaging structure has been provided, which comprises: multiple chips 101, 102, 103, a substrate 2 and a heat sink cover 3; the plurality of chips are mounted on the substrate 2; the heat sink cover 3 includes a supporting part 301 and a top cover 302, the supporting part 301 is bonded to the substrate 2, and surrounds the chips; the top cover 302 is supported by the supporting part 301 and covers the chips, and the top cover 302 includes slits 4 whose positions align to gaps near or between the chips. A first window can be formed in the top cover 5, and partially exposes a high-power-density chip 103 of the f chips; a second window 6 next to the high-power-density chip 103 can also be formed in the supporting part 302. By providing the slits 4, top window 5, and side window 6 in the heat sink cover 3, the present disclosure can minimize heat transfer between the chips and reduce the risk of thermal crosstalk while retaining package warpage control.

Therefore, the present disclosure effectively overcomes various shortcomings of the current techniques and has a high value for industrial application.

The above-mentioned embodiments only exemplarily illustrate the principles and effects of the present disclosure, but are not used to limit the present disclosure. Any person skilled in the art may modify or change the above embodiments without violating the spirit and scope of the present disclosure. Therefore, all equivalent modifications or changes made by those skilled in the art without departing from the spirit and technical concepts disclosed by the present disclosure should still be covered by the attached claims of the present disclosure.

What is claimed is:

1. An electronic packaging structure, comprising: one of more chips, a substrate, and a heat sink cover;
wherein the one or more chips are mounted on the substrate;
wherein the heat sink cover includes a supporting part and a top cover, wherein the supporting part is bonded to the substrate and surrounds the chips; wherein the top cover is disposed above the one or more chips and supported by the supporting part, and wherein the top cover comprises slits, wherein the slits have positions aligned to gaps near or between the one or more chips.

2. The electronic packaging structure according to claim 1, wherein the one or more chips comprise one high-power-density chip, wherein a first window is formed in the top cover and partially exposes the high-power-density chip.

3. The electronic packaging structure according to claim 2, wherein an area of the first window is greater than or equal to an area of an upper surface of the high-power-density chip.

4. The electronic packaging structure according to claim 2, wherein a second window next to the high-power-density chip is formed in the supporting part.

5. The electronic packaging structure according to claim 1, wherein a total area of the slits is less than or equal to a total area of the gaps near or between the one or more chips.

6. The electronic packaging structure according to claim 1, wherein each of the slits comprises sub-slits, and wherein each of the sub-slits is arranged in an array.

7. The electronic packaging structure according to claim 1, further comprising a first thermal interface material layer, wherein the top cover is adhered to upper surfaces of the one or more chips through the first thermal interface material layer.

8. The electronic packaging structure according to claim 1, further comprising a second thermal interface material layer, wherein the top cover is adhered to an external heat sink through the second thermal interface material layer.

9. The electronic packaging structure according to claim 1, wherein the supporting part is bonded to the substrate by a sealant.
